(19) United States
(12) Patent Application Publication
(10) Pub. No.: US 2025/0322982 A1
(43) Pub. Date: Oct. 16, 2025

(54) COAXIAL CABLE AND DEVICE TESTING APPARATUS

(71) Applicant: ADVANTEST Corporation, Tokyo (JP)

(72) Inventor: Wataru Saeki, Tokyo (JP)

(73) Assignee: ADVANTEST Corporation, Tokyo (JP)

(21) Appl. No.: 19/040,384

(22) Filed: Jan. 29, 2025

(30) Foreign Application Priority Data
Apr. 11, 2024 (JP) 2024-064207

(51) Int. Cl. H01B 11/18; G01R 31/319

(52) U.S. Cl. CPC H01B 11/1808; G01R 31/31926

(57) ABSTRACT

A coaxial cable includes a tubular outer conductor, an insulator covered with the tubular outer conductor, and inner conductors disposed in the insulator.

### CROSS-REFERENCE TO RELATED APPLICATIONS

The present application claims priority from Japanese Patent Application No. 2024-064207 filed on Apr. 11, 2024. The contents of this application are incorporated herein by reference in their entirety.

### BACKGROUND

### Technical Field

The present invention relates to a coaxial cable and a device testing apparatus including the coaxial cable.

### Discussion of the Background

As a semiconductor device testing apparatus for testing the electrical characteristics of various semiconductor devices (DUT) such as semiconductor integrated circuit elements, an apparatus includes a DSA including sockets, a test head including pin electronic cards, and a motherboard including coaxial cables electrically connecting the DSA and the test head (refer to, for example, Patent Document 1).

### Patent Document

PATENT DOCUMENT 1: JP 2008-078048 A

In a semiconductor device testing apparatus, as the number of simultaneous measurements (the number of DUTs that can be tested simultaneously) increases, the number of coaxial cables including in the motherboard also increases. On the other hand, because the space in the housing of the motherboard is limited, it may be difficult to increase the number of coaxial cables.

### SUMMARY

One or more embodiments provide a coaxial cable that can be arranged at high density and a device testing apparatus including the coaxial cable.

An aspect 1 of one or more embodiments is a coaxial cable comprising: an outer conductor being tubular; an insulator covered with the outer conductor; and a plurality of inner conductors disposed in the insulator.

An aspect 2 of one or more embodiments may be the coaxial cable of the aspect 1, wherein the plurality of inner conductors may be disposed in the insulator so that the plurality of inner conductors are spaced apart from each other.

An aspect 3 of one or more embodiments may be the coaxial cable of the aspect 1 or 2, wherein the insulator may be interposed between the plurality of inner conductors.

An aspect 4 of one or more embodiments may be the coaxial cable of any one of the aspects 1 to 3, wherein each of the inner conductors may have a cross-sectional shape extending in an arc shape.

An aspect 5 of one or more embodiments may be the coaxial cable of any one of the aspects 1 to 4, wherein each of the inner conductors may have a cross-sectional shape extending substantially parallel to an inner peripheral surface of the outer conductor.

An aspect 6 of one or more embodiments may be the coaxial cable of any one of the aspects 1 to 5, wherein a thickness of the inner conductor in a radial direction of the coaxial cable may be smaller than a width of the inner conductor in a circumferential direction of the coaxial cable.

An aspect 7 of one or more embodiments may be the coaxial cable of the aspect 6, wherein the thickness of the inner conductor may be equal to or less than ⅕ of the width of the inner conductor.

An aspect 8 of one or more embodiments may be the coaxial cable of any one of the aspects 1 to 7, wherein a thickness of the inner conductor in a radial direction of the coaxial cable may be substantially constant in a circumferential direction of the coaxial cable.

An aspect 9 of one or more embodiments may be the coaxial cable of any one of the aspects 1 to 8, wherein the plurality of inner conductors may be arranged at intervals in a circumferential direction of the coaxial cable and are arranged concentrically with the outer conductor.

An aspect 10 of one or more embodiments may be the coaxial cable of the aspect 9, wherein the plurality of inner conductors may be arranged at substantially equal intervals in the circumferential direction of the coaxial cable.

An aspect 11 of one or more embodiments may be the coaxial cable of any one of the aspects 1 to 10, wherein a distance between the plurality of inner conductors may be wider than the distance between the inner conductor and the outer conductor.

An aspect 12 of one or more embodiments may be the coaxial cable of any one of the aspects 1 to 11, wherein the inner conductor may comprise: a metal layer having an arc-shaped cross-sectional shape; or a plurality of metal wires arranged in an arc shape.

An aspect 13 of one or more embodiments may be the coaxial cable of any one of the aspects 1 to 12, wherein the insulator may comprise a first insulator comprising a resin material.

An aspect 14 of one or more embodiments may be the coaxial cable of the aspect 13, wherein the first insulator may be a resin body being columnar or tubular and holding the plurality of inner conductors, and the outer conductor may cover the resin body.

An aspect 15 of one or more embodiments may be the coaxial cable of the aspect 14, wherein the plurality of inner conductors may be embedded in the resin body.

An aspect 16 of one or more embodiments may be the coaxial cable of the aspect 13, wherein the first insulator may comprise a wire assembly that comprises a plurality of resin wires assembled together and holds the plurality of inner conductors, and the outer conductor may cover the wire assembly.

An aspect 17 of one or more embodiments may be the coaxial cable of the aspect 16, wherein the inner conductor may be disposed between the resin wires.

An aspect 18 of one or more embodiments may be the coaxial cable of any one of the aspects 13 to 17, wherein the insulator may comprise a second insulator comprises a gas or a vacuum.

An aspect 19 of one or more embodiments may be the coaxial cable of the aspect 18, wherein the second insulator may be interposed between the plurality of inner conductors.

An aspect 20 of one or more embodiments may be the coaxial cable of the aspect 18 or 19, wherein the first insulator may have a hole formed inside the first insulator, and the second insulator may be a gas or a vacuum in the hole.

An aspect 21 of one or more embodiments may be the coaxial cable of any one of the aspects 18 to 20, wherein the second insulator may be interposed between the inner conductor and the outer conductor.

An aspect 22 of one or more embodiments may be the coaxial cable of any one of the aspects 18 to 21, wherein the first insulator may have a groove formed on an outer peripheral surface of the first insulator, and the second insulator may be a gas or a vacuum in the groove.

An aspect 23 of one or more embodiments may be the coaxial cable of any one of the aspects 18 to 22, wherein the plurality of inner conductors may be exposed to the second insulator.

An aspect 24 of one or more embodiments may be the coaxial cable of any one of the aspects 1 to 23, wherein the coaxial cable may comprise: a plurality of wall-shaped conductors interposed between the plurality of inner conductors in a circumferential direction of the coaxial cable, and each of the plurality of wall-shaped conductors may be electrically connected to the outer conductor.

An aspect 25 of one or more embodiments may be the coaxial cable of the aspect 24, wherein each of the wall-shaped conductors may be connected to the outer conductor and may protrude from the outer conductor toward a center of the coaxial cable.

An aspect 26 of one or more embodiments may be the coaxial cable of the aspect 24 or 25, wherein the plurality of wall-shaped conductors may be connected to each other at a center of the coaxial cable.

An aspect 27 of one or more embodiments may be the coaxial cable of the aspect 26, wherein the coaxial cable may comprise: a center conductor disposed at the center of the coaxial cable, and the plurality of wall-shaped conductors may be connected to each other via the center conductor at the center of the coaxial cable.

An aspect 28 of one or more embodiments may be the coaxial cable of the aspect 26, wherein the plurality of wall-shaped conductors may be directly connected to each other at the center of the coaxial cable.

An aspect 29 of one or more embodiments may be the coaxial cable of any one of the aspects 24 to 28, wherein the wall-shaped conductor may comprise: a metal layer having a cross-sectional shape extending in a radial direction of the coaxial cable; or a plurality of metal wires arranged in the radial direction.

An aspect 30 of one or more embodiments may be the coaxial cable of any one of the aspects 1 to 29, wherein the insulator may be disposed in the outer conductor.

An aspect 31 of one or more embodiments may be the coaxial cable of any one of the aspects 1 to 30, wherein the outer conductor may collectively surround the plurality of inner conductors via the insulator.

An aspect 32 of one or more embodiments may be the coaxial cable of any one of the aspects 1 to 31, wherein the coaxial cable may comprise a jacket covering the outer conductor.

An aspect 33 of one or more embodiments may be the coaxial cable of any one of the aspects 1 to 32, wherein the coaxial cable may be used in a device testing apparatus that tests a device under test (DUT).

An aspect 34 of one or more embodiments is a device testing apparatus that tests a device under test (DUT), the device testing apparatus comprising the coaxial cable of any one of the aspects 1 to 33.

An aspect 35 of one or more embodiments may be the device testing apparatus of the aspect 34, wherein the plurality of inner conductors may transmit different electrical signals from each other.

According to one or more embodiments, the coaxial cable comprises the plurality of inner conductors disposed in the insulator. Therefore, it is possible to arrange the coaxial cables at high density.

### BRIEF DESCRIPTION OF THE DRAWINGS

FIG. 1 is a schematic cross-sectional view showing the overall configuration of the device testing apparatus in a first example of one or more embodiments.

FIG. 2 is an exploded sectional view showing the DSA and the motherboard in the first example and a view corresponding to the section II in FIG. 1.

FIG. 3 is a sectional view showing the coaxial cable in the first example.

FIG. 4 is a sectional view showing a modification of the coaxial cable in the first example.

FIG. 5 is a sectional view showing the coaxial cable in a second example of one or more embodiments.

FIG. 6 is a sectional view showing the coaxial cable in a third example of one or more embodiments.

FIG. 7 is a sectional view showing a first modification of the coaxial cable in the third example.

FIG. 8 is a sectional view showing a second modification of the coaxial cable in the third example.

FIG. 9 is a sectional view showing the coaxial cable in a fourth example of one or more embodiments.

FIG. 10 is a sectional view showing the coaxial cable in a fifth example of one or more embodiments.

### DESCRIPTION OF THE EMBODIMENTS

Hereinafter, embodiments will be described with reference to the drawings.

### First Example

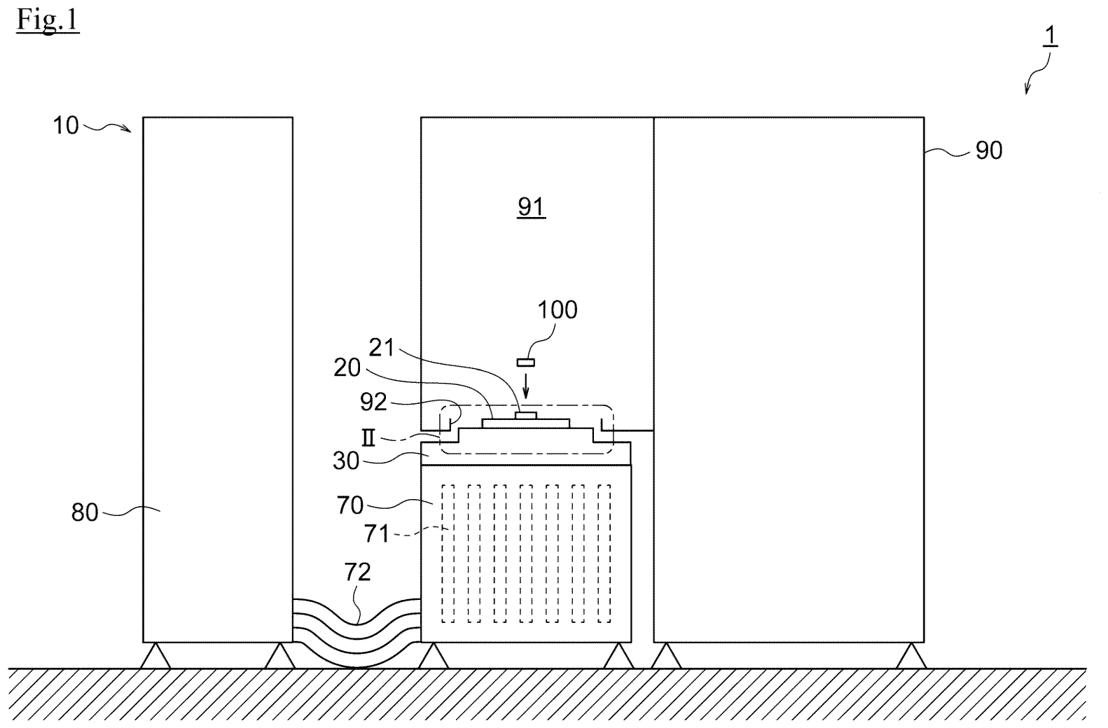

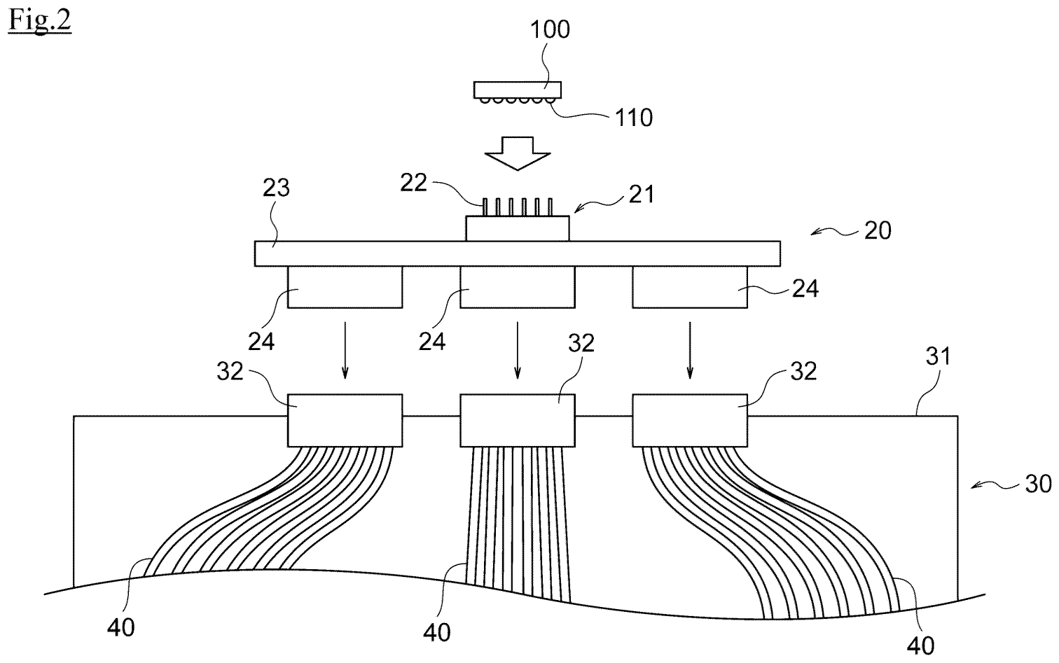

FIG. 1 is a schematic cross-sectional view showing the overall configuration of the device testing apparatus 1 in a first example of one or more embodiments. FIG. 2 is an exploded sectional view showing the DSA 20 and the motherboard 30 in a first example of one or more embodiments and a view corresponding to the section II in FIG. 1.

The device testing apparatus 1 in the present example is an apparatus that tests the electrical characteristics of a semiconductor device (hereinafter also simply referred to as “DUT”) 100 such as a semiconductor integrated circuit element. Although not particularly limited, a memory device, a logic device, and SoC (System on chip) can be exemplified as a specific example of the DUT 100 to be tested. As shown in FIG. 1, the device testing apparatus 1 includes a tester 10 that tests the DUT 100, and a handler 90 that handles the DUT 100 and presses the DUT 100 against a socket 21. The tester 10 includes a DSA 20, a motherboard 30, a test head 70, and a main frame 80. The configuration of the tester 10 is not particularly limited to the following as long as it includes the coaxial cable 40.

As shown in FIG. 1 and FIG. 2, the DSA (Device Specific Adapter) 20 includes a socket 21, a socket board 23, and a plurality of connectors 24. The DSA 20 is electrically connected to the test head 70 via the motherboard 30. The DSA 20 is detachable from the motherboard 30. The DSA 20 is designed according to the type of the DUT 100, and the DSA 20 is replaced with one corresponding to the type when changing the type of DUT 100. The number of DSAs 20 mounted on the motherboard 30 is not particularly limited, and a plurality of DSAs 20 may be mounted on the motherboard 30.

When testing the DUT 100, the DUT 100 is pressed against the socket 21 by the handler 90, therefore the DUT 100 and the socket 21 are electrically connected. The socket 21 includes a plurality of contactors 22 that respectively contact terminals 110 of the DUT 100. Although not particularly limited, a pogo pin, a vertical-type probe needle, a cantilever-type probe needle, an anisotropic conductive rubber sheet, a bump provided on a membrane, or a contactor manufactured using MEMS technology can be exemplified as a specific example of the contactor 22.

The socket board 23 is a wiring board with the above-described socket 21 mounted on its upper surface. The number of sockets 21 mounted on the socket board 23 is not particularly limited, and a plurality of sockets 21 may be mounted on the socket board 23. Further, although not particularly illustrated, a socket guide for positioning the DUT 100 with respect to the socket 21 may be attached to the upper surface of the socket board 23. The coaxial connector 24 is mounted on the lower surface of the socket board 23. The socket 21 and the coaxial connector 24 are electrically connected via a conductive path (not shown) such as a wiring pattern and a through hole formed in the socket board 23.

The motherboard 30 is a relaying device that electrically connects the DSA 20 and the test head 70. The motherboard 30 includes a housing 31, a plurality of coaxial connectors 32, and a plurality of coaxial cables 40. Although not particularly limited, for example, the motherboard 30 includes 100 or more coaxial connectors 32, and 50 to 100 coaxial cables 40 are connected to one coaxial connector 32, and as a result, the motherboard 30 includes several thousand to tens of thousands of coaxial cables 40. The coaxial connector 32 is connected to one end (the upper end in FIG. 2) of the coaxial cable 40. The coaxial connector 32 can be fitted into the coaxial connector 24 of the DSA 20 described above. The coaxial connector 32 is held by the upper part of the housing 31 to correspond to the coaxial connector 24 of the DSA 20. When the DSA 20 is attached to the motherboard 30, the coaxial connector 24 of the DSA 20 and the coaxial connector 32 of the motherboard 30 are fitted together. The configuration of the coaxial cable 40 will be described in detail later.

As shown in FIG. 1, the test head 70 accommodates therein a test module (pin electronics card) 71 for testing the DUT 100. The test module 71 is a wiring board on which electronic devices such as test devices used for testing the DUT 100 are mounted. The test module 71 is electrically connected to the coaxial cable 40 of the motherboard 30 via a coaxial connector (not shown) or the like connected to the other end of the coaxial cable 40. The test module 71 tests the DUT 100 by transmitting and receiving test signals to and from the DUT 100 via the DSA 20 and the motherboard 30. The test head 70 is connected to the main frame 80 via a cable 72.

The main frame (tester main body) 80 is, for example, a computer that executes a program, and the main frame 80 communicates with the test modules 71 in the test head 70 according to the program to control the test modules 71. Each of the test module 71 generates test signals according to instructions from the main frame 80 and outputs the test signals to the DUT 100.

Although not particularly illustrated, the handler 90 includes, for example, a transport device that transports the test tray on which the DUT 100 is mounted above the DSA 20, a pressing device that presses the DUT 100 against the socket 21 of the DSA 20, and a sorting device that sorts the DUT 100 according to the test result while taking the DUT 100 out from the test tray.

The handler 90 also includes a chamber 91 as a temperature adjusting device that applies high or low temperature thermal stress to the DUT 100. The chamber 91 includes a thermostatic chamber capable of maintaining the temperature in the chamber at a desired temperature. Therefore, the device testing apparatus 1 is capable of testing the DUT 100 while applying thermal stress to the DUT 100, and a so-called high-temperature test and a low-temperature test can be performed.

The DSA 20 enters the chamber 91 through an opening 92 formed in the handler 90, and the socket 21 of the DSA 20 is disposed in the chamber 91. The DUT 100 and the socket 21 are electrically connected by pressing the DUT 100 against the socket 21 of the DSA 20 by the pressing device of the handler 90.

The handler 90 may be of a type where the handler includes a contact arm that suction-holds and moves the DUT 100 without using a test tray and the contact arm presses the DUT 100. In this case, the handler 90 may include a heater or a heat sink provided in the front end of the contact arm as a temperature adjusting device instead of the chamber 91. Alternatively, the handler 90 may include, in addition to the chamber 91, a heater or a heat sink provided in the front end of the contact arm as a temperature adjusting device.

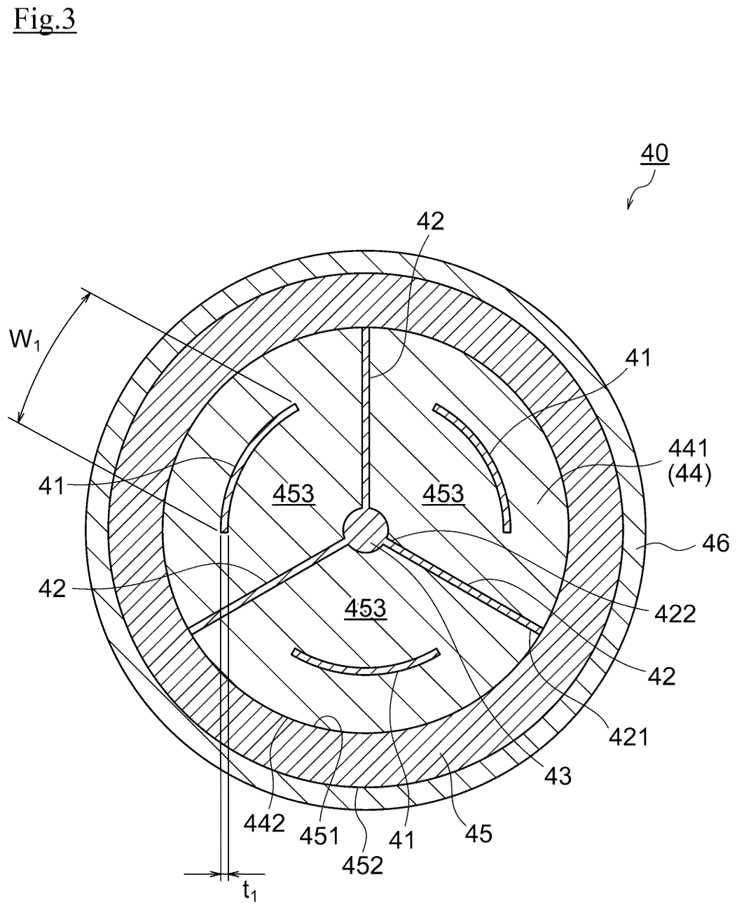

Next, the configuration of the coaxial cable 40 included in the motherboard 30 described above will be described in detail with reference to FIG. 3. FIG. 3 is a sectional view showing the coaxial cable 40 in a first example of the one or more embodiments.

As shown in FIG. 3, the coaxial cable 40 in the present example includes a plurality of inner conductor 41, a plurality of wall-shaped conductors 42, a center conductor 43, an insulator 44 holding these conductors 41 to 43, an outer conductor 45 covering the insulator 44, and a jacket 46 covering the outer conductor 45. The coaxial cable 40 is a cable extending in the normal direction of the paper surface of FIG. 3, and FIG. 3 shows a cross section perpendicular to the longitudinal direction (axial direction) of the coaxial cable 40.

Each of the plurality of inner conductor 41 functions as a transmission path for transmitting an electrical signal between the test head 70 and the DUT 100. On the other hand, the outer conductor 45 is connected to ground and functions as an electromagnetic shield layer for shielding noises. The wall-shaped conductors 42 and center conductor 43 have a function of suppressing crosstalk between the plurality of inner conductors 41. In the device testing apparatus 1 described above, the electrical signal flowing through the inner conductor 41 is a high frequency electrical signal and is an electrical signal with a frequency of 10 MHz or more, an electrical signal with a frequency of 100 MHz or more, an electrical signal with a frequency of 1 GHz or more, an electrical signal with a frequency of 2.5 GHz or more, an electrical signal with a frequency of 5 GHz or more, or an electrical signal with a frequency of 10 GHz or more. Different electrical signals are assigned to the plurality of inner conductors 41, and a single coaxial cable 40 can transmit a plurality of (three in the present example) electrical signals.

The coaxial cable 40 in the present example includes three inner conductors 41. Each of the inner conductors 41 is a conductive layer extending over the entire area in the axial direction of the coaxial cable 40. Each of the inner conductors 41 has an arc-shaped cross-sectional shape. Each of the inner conductors 41 extends substantially parallel to the inner peripheral surface 451 of the outer conductor 45, and a microstrip line structure is formed between the inner conductor 41 and the outer conductor 45. As long as the number of the inner conductors 41 included in the coaxial cable 40 is plural, it is not particularly limited to the above.

The inner conductor 41 has a tape-like cross-sectional shape. That is, the thickness t1 of the inner conductor 41 in the radial direction of the coaxial cable 40 is smaller than the width w1 of the inner conductor 41 in the circumferential direction of the coaxial cable 40 (t1<w1). Although not particularly limited, the thickness t1 of the inner conductor 41 is preferably equal to or less than ⅕ of the width w1 of the inner conductor 41 (t1≤w1×⅕), and more preferably equal to or less than 1/10 of the width w1 of the inner conductor 41 (t1≤w1× 1/10). The thickness t1 of the inner conductor 41 is substantially constant in the circumferential direction of the coaxial cable 40.

The thickness t1 of the inner conductor 41 is, for example, preferably equal to or more than 0.1 μm and equal to or less than 20 μm (0.1 m≤t≤10 μm), and more preferably equal to or more than 0.1 μm and equal to or less than 10 m (0.1 m≤t1≤10 μm). It is possible to set the thickness t1 of the inner conductor 41 according to the frequency of the electrical signal flowing through the coaxial cable 40. Specifically, the thickness t1 of the inner conductor 41 is set to be thinner as the frequency of the electric signal is higher, and the thickness t1 of the inner conductor 41 is set to be thicker as the frequency of the electric signal is lower.

The inner conductor 41 is made of a material having electrical conductivity. Specifically, although not particularly limited, the inner conductor 41 is formed of a metal foil. A copper foil and a silver-plated copper foil can be exemplified as a specific example of the metal foil constituting the inner conductor 41. The inner conductor 41 may be a thin film formed by a plating method such as electrolytic plating or electroless plating. Alternatively, the inner conductor 41 may be thin film formed by physical vapor deposition method (PVD) such as vacuum deposition or sputtering, or chemical vapor deposition method (CVD). Alternatively, the inner conductor 41 may be a thin film formed by applying a coating material containing metal particles and an adhesive and curing the coating material by heating.

The coaxial cable 40 in the present example includes three wall-shaped conductors 42. Each of the wall-shaped conductors 42 is a conductive layer extending over the entire area in the axial direction of the coaxial cable 40. Each of the wall-shaped conductors 42 has a tape-like cross-sectional shape extends linearly in the radial direction of the coaxial cable 40. Each of the wall-shaped conductors 42 is connected to the outer conductor 45 at one end 421 of the wall-shaped conductor 42 and protrudes from the outer conductor 45 toward the center of the coaxial cable 40. Therefore, each of the wall-shaped conductors 42 is connected to ground via the outer conductor 45. The number of the wall-shaped conductors 42 included in the coaxial cable 40 is not particularly limited to the above, and it is possible to set the number of the wall-shaped conductors 42 according to the number of the inner conductors 41 included in the coaxial cable 40.

Similar to the inner conductor 41 described above, the wall-shaped conductor 42 is made of a material having electrical conductivity. Specifically, although not particularly limited, the wall-shaped conductor 42 is formed of a metal foil. A copper foil and a silver-plated copper foil can be exemplified as a specific example of the metal foil constituting the wall-shaped conductor 42. The wall-shaped conductor 42 may be a thin film formed by a plating method such as electrolytic plating or electroless plating. Alternatively, the wall-shaped conductor 42 may be thin film formed by physical vapor deposition method (PVD) such as vacuum deposition or sputtering, or chemical vapor deposition method (CVD). Alternatively, the wall-shaped conductor 42 may be a thin film formed by applying a coating material containing metal particles and an adhesive and curing the coating material by heating.

The center conductor 43 is a single wire extending over the entire axial direction of the coaxial cable 40. The center conductor 43 has a circular cross-sectional shape and is a solid wire made of a material having electrical conductivity. A twisted wire may be used as the center conductor 43.

The center conductor 43 is disposed at the center of the coaxial cable 40. Each of the wall-shaped conductors 42 is connected to the center conductor 43 at the other end 422 of the wall-shaped conductor 42, and all of the wall-shaped conductors 42 are electrically connected to each other via the center conductor 43. Therefore, the center conductor 43 is connected to ground via the wall-shaped conductors 42 and the outer conductor 45. Although the metal material of which the center conductor 43 is made is not limited as long as it is a metal material having good electrical conductivity, for example, silver, copper, or an alloy thereof can be exemplified as a specific example of the metal material of which the center conductor 43 is made.

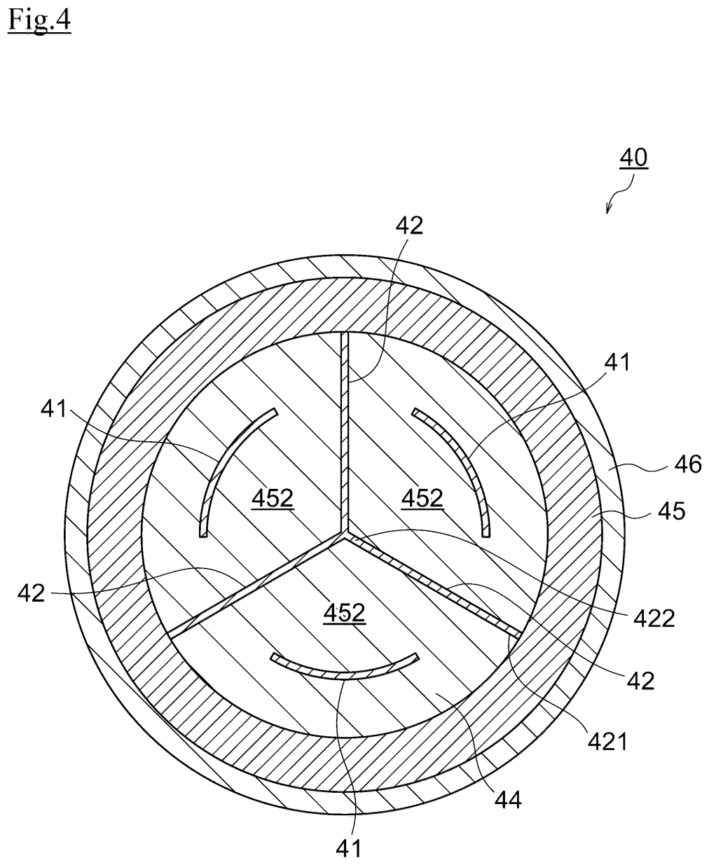

As shown in FIG. 4, the coaxial cable 40 may not include the central conductor 43. In this case, all of the wall-shaped conductors 42 are electrically connected to each other by directly connecting the wall-shaped conductors 42 to each other at the other ends 422 of the wall conductors 42. FIG. 4 is a sectional view showing the modification of the coaxial cable 40 in a first example of one or more embodiments.

Returning to FIG. 3, the insulator 44 includes a resin body 441 being columnar and extending over the entire axial direction of the coaxial cable 40. The above-mentioned inner conductors 41, wall-shaped conductors 42, and central conductor 43 are embedded in the resin body 441. The resin body 441 is made of a resin material having an electrically insulation property. Although not particularly limited, imide-based resin such as polyimide, fluororesin such as polytetrafluoroethylene (PTFE), polyethylene (PE), and crosslinked foamed polyethylene can be exemplified as a specific example of the resin material of which the resin body 441 is made.

The plurality of inner conductors 41 are arranged at substantially equal intervals in the circumferential direction of the coaxial cable 40. The plurality of inner conductors 41 are also arranged concentrically with the outer conductor 45. The resin body 441 is interposed between the inner conductors 41 adjacent to each other.

The plurality of wall-shaped conductors 42 are disposed in the resin body 441 so that each of the wall-shaped conductors 42 is interposed between the inner conductors 41 adjacent to each other in the circumferential direction of the coaxial cable 40. Each of the wall-shaped conductors 42 is preferably arranged at the center between the inner conductors 41 adjacent to each other. It is possible to suppress crosstalk between the plurality of inner conductors 41 by the wall conductors 42. The resin body 441 is interposed between the wall-shaped conductor 42 and the inner conductor 41.

The center conductor 43 is disposed at the center of the resin body 441, and the other ends 422 of the plurality of wall-shaped conductors 42 are connected to the center conductor 43. It is possible to further suppress crosstalk between the plurality of inner conductors 41 by connecting all of the wall-shaped conductors 42 with the center conductor 43. The resin body 441 is interposed between the center conductor 43 and the inner conductor 41.

When the inner conductors 41 and the wall-shaped conductors 42 are metal foils, for example, the resin body 441 in which the conductors 41 to 43 are embedded can be formed by extruding a resin material in a state where the conductors 41 to 43 are arranged as described above. When the inner conductors 41 and the wall-shaped conductors 42 are thin films formed by a plating method or the like, for example, the resin body 441 in which the conductors 41 to 43 are embedded can be formed by repeatedly extruding a core material that constitutes a part of the insulator 44 and forming a thin film on the core material.

The outer conductor 45 is a tubular conductive layer that covers the entire outer peripheral surface 442 of the resin body 441 and extends over the entire axial direction of the coaxial cable 40. The resin body 441 is disposed in the outer conductor 45, and the outer conductor 45 collectively surrounds all of the inner conductors 41 via the resin body 441. The resin body 441 is interposed between the outer conductor 45 and each of the inner conductors 41. As described above, each of the wall-shaped conductors 42 is connected to the outer conductor 45 at one end 421 of the wall-shaped conductor 42, and each of the wall-shaped conductors 42 is connected to the center conductor 43 at the other end 422 of the wall-shaped conductor 42. As a result, the inner space of the outer conductor 45 is divided into three rooms 453 by the wall-shaped conductors 42 and the center conductor 43, and each room 453 individually accommodates the inner conductor 41.

The outer conductor 45 is a thin film formed on the outer peripheral surface 442 of the resin body 441. The thin film is made of a metal material. The thin film is, for example, a plated layer formed by a plating method such as electrolytic plating or electroless plating. Although a specific example of the metal material of which the outer conductor 45 is made is not particularly limited as long as it is a metal material having good electrical conductivity, for example, silver, copper, or alloys thereof can be exemplified.

The method of forming the thin film of the outer conductor 45 is not limited to the above-described plating method, and the outer conductor 45 may be formed by, for example, physical vapor deposition method (PVD) or chemical vapor deposition method (CVD). Alternatively, the thin film of the outer conductor 45 may be a coating layer. Although not particularly limited, the coating layer may be formed, for example, by applying a coating material containing metal particles and an adhesive to the outer peripheral surface 442 of the insulator 44 and curing the coating material by heating.

Alternatively, the outer conductor 45 may be formed of a metal foil instead of the thin film described above. In this case, the outer conductor 45 is formed by wrapping the metal foil around the outer peripheral surface 442 of the resin body 441. Although not particularly limited, for example, a copper foil and a silver-plated copper foil can be exemplified as a specific example of the metal foil constituting the outer conductor 45. Alternatively, instead of the thin film described above, a metal pipe such as a copper pipe may be used as the outer conductor 45. Alternatively, instead of the thin film described above, a braided shield that includes a plurality of metal wires braided together may be used as the outer conductor 45.

The jacket 46 is a tubular member that covers the entire outer peripheral surface 452 of the outer conductor 45. The jacket 46 covers the outer conductor 45 over the entire axial direction of the coaxial cable 40. The jacket 46 is made of a resin material having an electrically insulation property. Although not particularly limited, for example, polyvinyl chloride (PVC), polyethylene (PE), polytetrafluoroethylene (PTFE), perfluoroalkoxy alkane (PFA), and fluorinated ethylene propylene (FEP) can be exemplified as a specific example of a resin material of which the jacket 46 is made.

Here, if the outer conductor of the coaxial cable is made too thin, the outer conductor may be easily broken. If the jacket of the coaxial cable is made too thin, sufficient insulation may not be ensured. There is a limit to how thin the coaxial cable can be due to the limitation of the thickness of the outer conductor and the thickness of the jacket, and therefore, there is a limit to the high-density arrangement of the coaxial cable to the motherboard by the reduction in the diameter of the coaxial cable.

On the other hand, in the present example, the coaxial cable 40 includes the plurality of inner conductors 41, and a single outer conductor 45 is shared by the plurality of inner conductors 41. Therefore, in the coaxial cable 40 having a transmission characteristic equivalent to those of the conventional coaxial cable with a single inner conductor, it is possible to reduce the cross-sectional area compared with the conventional coaxial cables of the same number as the number (three in this example) of the inner conductor 41. Accordingly, in the present example, it is possible to arrange the coaxial cables 40 in the motherboard 30 at high density.

Because the inner conductor of the conventional coaxial cable described above is a metal wire having a circular cross-sectional shape, the rigidity of the coaxial cable is relatively high. Further, a plurality of coaxial cables may be connected to one connector. In this case, the reaction force from the coaxial cable becomes stronger as the number of coaxial cables is increased. Therefore, when assembling the motherboard, the coaxial cable itself may break or cracks may occur at the soldered joint between the inner conductor of the coaxial cable and the terminal of the coaxial connector due to forcibly pushing the coaxial cable or the like, and a connection failure may occur.

On the other hand, in the present example, because each of the inner conductors 41 has a cross-sectional shape extending in an arc shape, it is possible to reduce the rigidity of the coaxial cable 40 and it is possible to reduce reaction force of the coaxial cable 40. In the present example, focusing on the fact that the frequency of the electric signals used in the device testing apparatus is high frequency and the electrical signals concentrate on the surface part of the conductor as the frequency of the electric signals is higher due to the skin effect, the cross-sectional shape of each of the inner conductors 41 is made thin, thus the reaction force of the coaxial cable 40 is reduced. Accordingly, it is possible to suppress the occurrence of disconnection when assembling the motherboard 30.

Further, in the device testing apparatus, in order to absorb mechanical errors when fitting connectors, there may be cases where the connecters include a sliding function that allows one connector (the connector to which the coaxial cable is connected) to slide with respect to the other connector (the connector mounted on the wiring board) in a lateral direction (perpendicular to the fitting direction).

On the other hand, in the present example, because the reaction force of the coaxial cable 40 can be reduced as described above, even when the connector 32 to which the coaxial cable 40 is connected includes the above-mentioned sliding function, it is possible to ensure sufficient contact pressure between the terminals of the connectors 32 and 24, and it is possible to suppress the occurrence of connection failures between the connectors 32 and 24.

Furthermore, in the device testing apparatus, the connector is inserted and removed every time the type of DUT is replaced. When a large number of coaxial cables connected to one connector is increased, because the connectors may be fitted together in an inclined state due to the strong reaction force from the coaxial cables, it may not be possible to ensure sufficient connection reliability in the insertion and removal of the connectors for several thousand times.

On the other hand, in the present example, because the reaction force of the coaxial cable 40 can be reduced as described above, it is possible to suppress the occurrence of fitting of the connector 32 in an inclined state with respect to the counterpart connector 24, and it is possible to ensure sufficient connection reliability in the insertion and removal of the connectors 32 and 24 for several thousand times.

When performing a low-temperature test (for example, a test of the DUT at −50° C. to−40° C.) in the device testing apparatus, if the inner conductor of the coaxial cable is a metal wire having a circular cross-sectional shape, heat may be transferred into the motherboard through the inner conductor, the inside of the motherboard may be cooled and dew condensation may occur.

On the other hand, in the present example, because the inner conductor 41 has a thin cross-sectional shape extending in an arc shape, it is possible to suppress heat transfer from the chamber 91 of the handler 90 to the inside of the motherboard 30 and it is possible to suppress formation of dew condensation inside the motherboard 30.

In the present example, because the inner conductor 41 has a thin cross-sectional shape extending in an arc shape, it is possible to reduce the weight of several thousand to tens of thousands of coaxial cables 40. Thus, it is possible to reduce the strength of the housing 31 holding the coaxial cable 40A, and it is possible to reduce the cost of the motherboard 30.

### Second Example

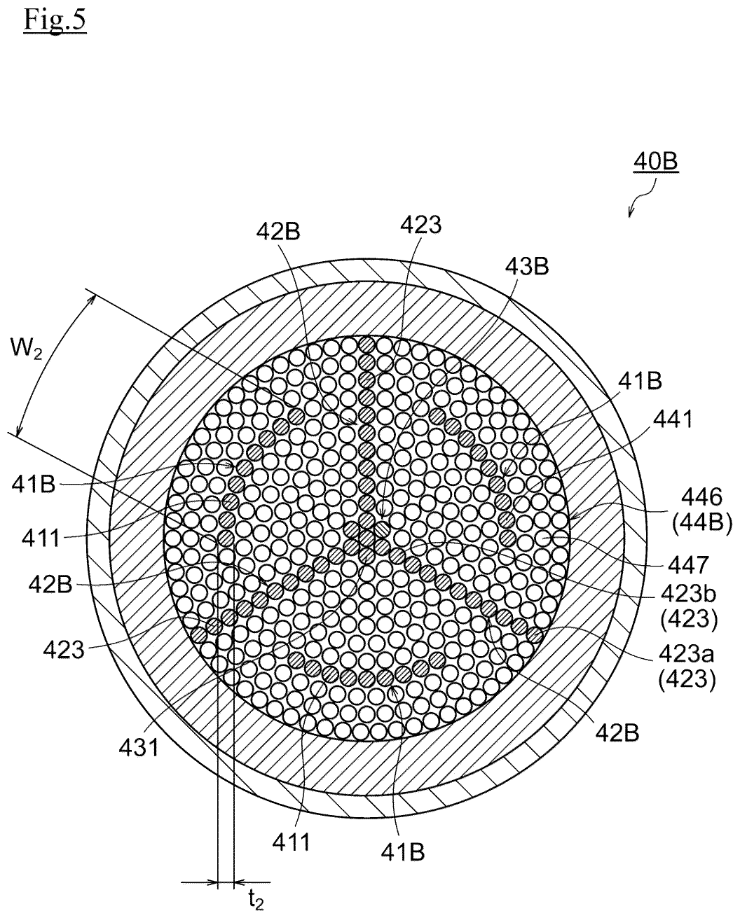

FIG. 5 is a sectional view showing the coaxial cable 40B in a second example of one or more embodiments. The present example is different from the first example in the configurations of the inner conductors 41B, the wall-shaped conductors 42B, and the insulator 44B, but other configurations are the same as those of the first example. Hereinafter, the coaxial cable 40B in the second example will be described only with respect to differences from the first example, parts having the same configuration as those in the first example are denoted by the same reference numerals, and description thereof will be omitted.

As shown in FIG. 5, each of the inner conductors 41 in the present example includes a plurality of metal wires 411 instead of a conductive layer. Each of the metal wires 411 extends over the entire area in the axial direction of the coaxial cable 40. The plurality of metal wires 411 are arranged in an arc, and as a result, each inner conductor 41B has a cross-sectional shape extending in an arc. The metal wires 411 are arranged substantially parallel to the inner circumferential surface 451 of the outer conductor 45, and a microstrip line structure is formed between the inner conductor 41B and the outer conductor 45. The number of the metal wires 411 included in each inner conductor 41B is not particularly limited as long as it is plural.

The thickness t2 of the inner conductor 41B in the radial direction of the coaxial cable 40B is smaller than the width w2 of the inner conductor 41B in the circumferential direction of the coaxial cable 40B (t2≤w2). Although not particularly limited, the thickness t2 of the inner conductor 41B is preferably equal to or less than ⅕ of the width w2 of the inner conductor 41B (t2≤w2×⅕), and more preferably equal to or less than 1/10 of the width w2 of the inner conductor 41B (t2≤w2× 1/10). In the present example, as described later, because the cross-sectional shape of the metal wire 411 is circular, the thickness t2 of the inner conductor 41B is equal to the diameter of the metal wire 411.

Each of the wall-shaped conductors 42B in the present example also includes a plurality of metal wires 423 instead of a conductive layer. Each of the metal wires 423 extends over the entire area in the axial direction of the coaxial cable 40. The plurality of metal wires 423 are arranged in a straight line in the radial direction of the coaxial cable 40B, and as a result, each wall-shaped conductor 42B has a cross-sectional shape extending in a straight line. The metal wire 423a located at one end of each wall-shaped conductor 42B is connected to the outer conductor 45, and the wall-shaped conductor 42B protrudes from the outer conductor 45 toward the center of the coaxial cable 40B. Therefore, each wall-shaped conductor 42B is connected to ground via the outer conductor 45. The number of the metal wires 423 included in each wall-shaped conductor 42B is not particularly limited as long as it is plural.

The center conductor 43B in the present example also includes a plurality of metal wires 431. Each of the metal wires 431 extends over the entire area in the axial direction of the coaxial cable 40. The plurality of metal wires 431 are arranged in a circular shape at the center of the coaxial cable 40B. The metal wire 423b located at the other end of each wall-shaped conductor 42B is connected to the center conductor 43B, and all of the wall-shaped conductors 42B are electrically connected to each other via the center conductor 43B. Therefore, the center conductor 43B is connected to ground via the wall-shaped conductors 42B and the outer conductor 45. The number of the metal wires 431 included in the center conductor 43B is not particularly limited as long as it is plural.

Each of the metal wires 411, 423, and 431 has a circular cross-sectional shape and is a solid wire made of a metal material having good electrical conductivity. Although not particularly limited, for example, silver, copper, or an alloy thereof can be exemplified as a specific example of the metal material of which the metal wires 411, 423, and 431 are made. Although the metal wires 411, 423, and 431 have the same diameter in the present example, the relationship of the diameters of the metal wires 411, 423, and 431 is not particularly limited to this, and the diameters of the metal wires 411, 423, and 431 may be different form each other.

In the present example, the insulator 44B includes a wire assembly 446 that holds the inner conductors 41B, the wall conductors 42B, and the center conductor 43B. The wire assembly 446 includes a plurality of resin wires 447 assembled together. The outer conductor 45 covers the wire assembly 446.

Each of the plurality of resin wires 447 has a circular cross-sectional shape and is a solid wire made of a resin material having an electrically insulation property. Each of the resin wires 447 extends over the entire area in the axial direction of the coaxial cable 40B. Although not particularly limited, for example, imide-based resin such as polyimide, fluororesin such as polytetrafluoroethylene (PTFE) and perfluoroalkoxy alkane (PFA), polyetheretherketone (PEEK), polyethylene (PE), and crosslinked foamed polyethylene can be exemplified as a specific example of the resin material of which the resin wire 447 is made. The resin wires 447 are arranged inside the outer conductor 45 so that the inner space of the outer conductor 45 is filled with the resin wires 447.

As in the first example described above, in the present example, the plurality of inner conductors 41B are arranged at substantially equal intervals in the circumferential direction of the coaxial cable 40B and are arranged concentrically with the outer conductor 45. Each of the plurality of wall-shaped conductor 42B is interposed between the inner conductor 41B adjacent to each other. It is possible to suppress crosstalk between the plurality of inner conductors 41B by the wall conductors 42B. The center conductor 43B to which the plurality of wall-shaped conductor 42B are connected is disposed at the center of the coaxial cable 40B. It is possible to further suppress crosstalk between the plurality of inner conductors 41B by connecting all of the wall-shaped conductors 42B with the center conductor 43B.

In the present example, the metal wires 411, 423, and 431 are arranged among the plurality of resin wires 447 so that the conductors 41B to 43B are arranged as described above. The inner conductors 41B, the wall-shaped conductors 42B, the center conductor 43B, and the insulator 44B in the present example are formed by twisting the wires 411, 423, 431, and 447 together in a state where the wires 411, 423, 431, and 447 are arranged in this manner.

In the present example, similarly to the first example described above, because the coaxial cable 40B includes the plurality of inner conductors 41B, it is possible to arrange the coaxial cables 40B in the motherboard 30 at high density.

Further, in the present example, similarly to the first example described above, because each of the plurality of inner conductors 41B has a thin cross-sectional shape extending in an arc shape, it is possible to reduce the reaction force of the coaxial cable 40B, to reduce the weight of the coaxial cables 40B, and to suppress formation of dew condensation inside the motherboard 30.

### Third Example

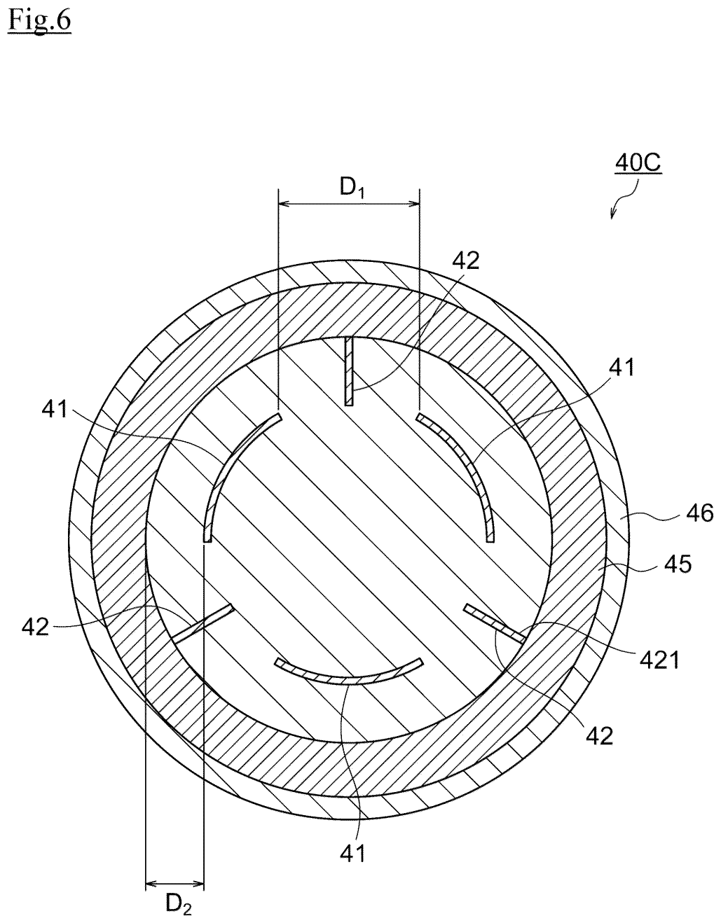

FIG. 6 is a sectional view showing the coaxial cable in a third example of one or more embodiments. The present example is different from the first example in that the coaxial cable 40C does not include the center conductor 43, but other configurations are the same as those of the first example. Hereinafter, the coaxial cable 40C in the third example will be described only with respect to differences from the first example, parts having the same configuration as those in the first example are denoted by the same reference numerals, and description thereof will be omitted.

As shown in FIG. 6, the coaxial cable 40C in the present example does not include the center conductor 43. Although each of the wall-shaped conductors 42 is connected to the outer conductor 45 at one end 421 of the wall-shaped conductor 42, the amount of protrusion of the wall-shaped conductor 42 from the outer conductor 45 is shorter than that in the first example. The wall-shaped conductor 42 may be interposed between the inner conductors 41 in the circumferential direction of the coaxial cable 40C. Because the wall-shaped conductor 42 is interposed between the inner conductors 41 adjacent to each other in the circumferential direction of the coaxial cable 40C, it is possible to suppress crosstalk between the plurality of inner conductors 41.

In the present example, similarly to the first example described above, because each of the inner conductors 41 has a cross-sectional shape extending substantially parallel to the inner peripheral surface 451 of the outer conductor 45, a microstrip line structure is formed between the inner conductor 41 and the outer conductor 45. In this case, it is preferable that the shortest distance D1 between adjacent inner conductors 41 is wider than the shortest distance D2 between the inner conductor 41 and the outer conductor 45 (D1>D2). Therefore, because the distance between the inner conductors 41 increases, and it is possible to further suppress crosstalk between the inner conductors 41.

In the present example, similarly to the first example described above, because the coaxial cable 40C includes the plurality of inner conductors 41, it is possible to arrange the coaxial cables 40C in the motherboard 30 at high density.

Further, in the present example, similarly to the first example described above, because each of the plurality of inner conductors 41 has a thin cross-sectional shape extending in an arc shape, it is possible to reduce the reaction force of the coaxial cable 40C, to reduce the weight of the coaxial cables 40C, and to suppress formation of dew condensation inside the motherboard 30.

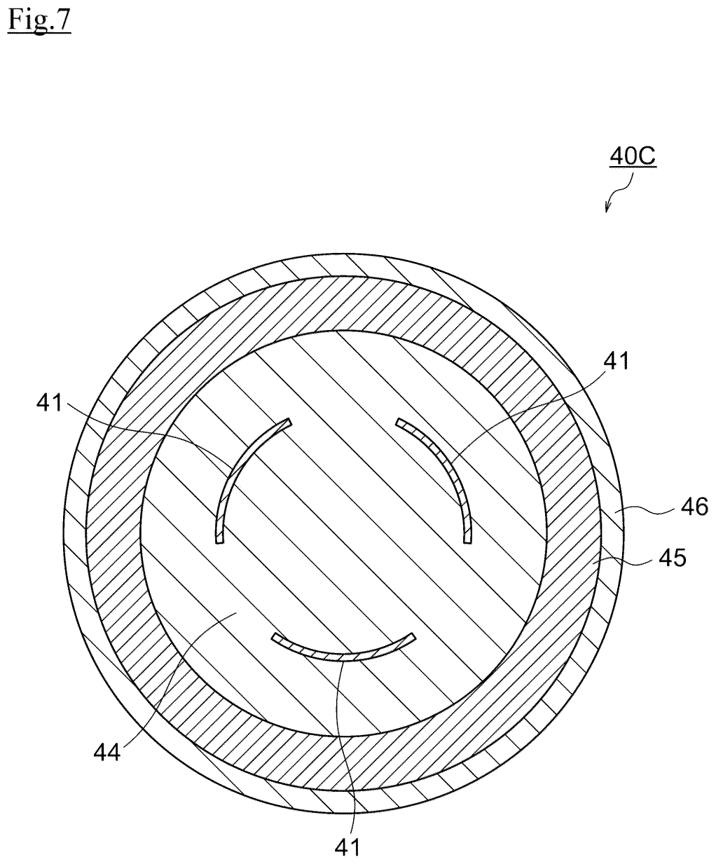

As shown in FIG. 7, the coaxial cable 40C does not include the wall-shaped conductors 42. FIG. 7 is a sectional view showing a first modification of the coaxial cable in the third example of one or more embodiments.

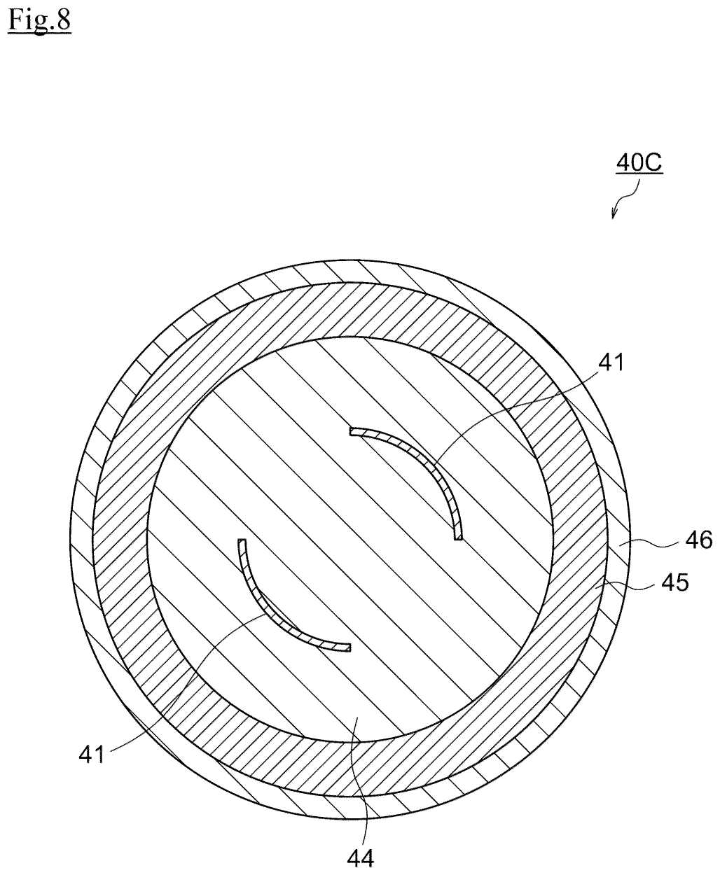

Furthermore, the number of the inner conductors 41 included in the coaxial cable 40C is not particularly limited to the above. For example, as shown in FIG. 8, the coaxial cable 40C may include two inner conductors 41. FIG. 8 is a sectional view showing a second modification of the coaxial cable in the third example of one or more embodiments. Alternatively, although not particularly illustrated, the coaxial cable 40 may include four or more inner conductors 41.

### Fourth Example

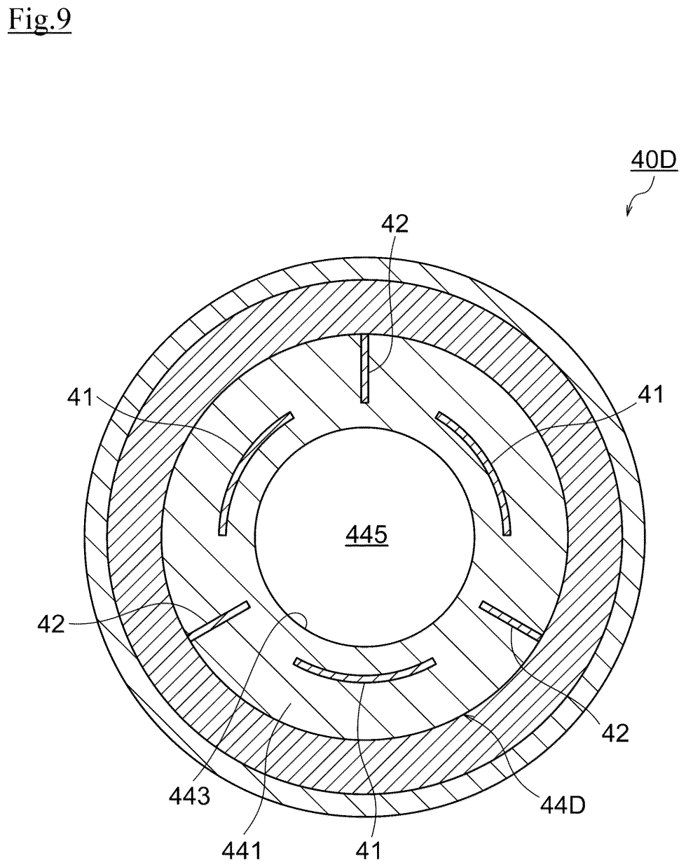

FIG. 9 is a sectional view showing the coaxial cable 40D in a fourth example of one or more embodiments. The present example is different from the third example in that the insulator 44D includes the air layer 445, but other configurations are the same as those of the third example. Hereinafter, the coaxial cable 40D in the fourth example will be described only with respect to differences from the third example, parts having the same configuration as those in the third example are denoted by the same reference numerals, and description thereof will be omitted.

As shown in FIG. 9, the insulator 44D in the present example includes the resin body 441 and the air layer 445. The resin body 441 of the present example has a tubular shape and has a hole 443 in its center. The hole 443 penetrates the resin body 441 over the entire axial direction of the coaxial cable 40D. The air that is present in the hole 443 forms the air layer 445. The air layer 445 is interposed between the plurality of inner conductors 41.

Instead of the air layer 445, a gas other than air may be present in the hole 443, or the inside of the hole 443 may be a vacuum. Although the inner conductor 41 is completely embedded inside the resin body 441 in FIG. 9, the inner conductor 41 may be exposed to the air layer 445 from the resin body 441.

In the present example, similarly to the third example described above, because the coaxial cable 40D includes the plurality of inner conductors 41, it is possible to arrange the coaxial cables 40D in the motherboard 30 at high density.

Further, in the present example, similarly to the third example described above, because each of the plurality of inner conductors 41 has a thin cross-sectional shape extending in an arc shape, it is possible to reduce the reaction force of the coaxial cable 40D, to reduce the weight of the coaxial cables 40D, and to suppress formation of dew condensation inside the motherboard 30.

Further, in the present example, similarly to the third example described above, because each of the inner conductors 41 has a cross-sectional shape extending substantially parallel to the inner peripheral surface 451 of the outer conductor 45, a microstrip line structure is formed between the inner conductor 41 and the outer conductor 45.

Further, in the present example, similarly to the third example described above, because the wall-shaped conductor 42 is interposed between the inner conductors 41 adjacent to each other in the circumferential direction of the coaxial cable 40D, it is possible to suppress crosstalk between the plurality of inner conductors 41.

Furthermore, in the present example, the air layer 445 is interposed between the plurality of inner conductors 41, and the dielectric constant of the portion of the insulator 44D between the inner conductors 41 is reduced, therefore it is possible to increase the electrical distance between the inner conductors 41. In addition, in the present example, it is possible to adjust the electrical distance between the inner conductors 41 by adjusting the size of the hole 443 in the resin body 441.

### Fifth Example

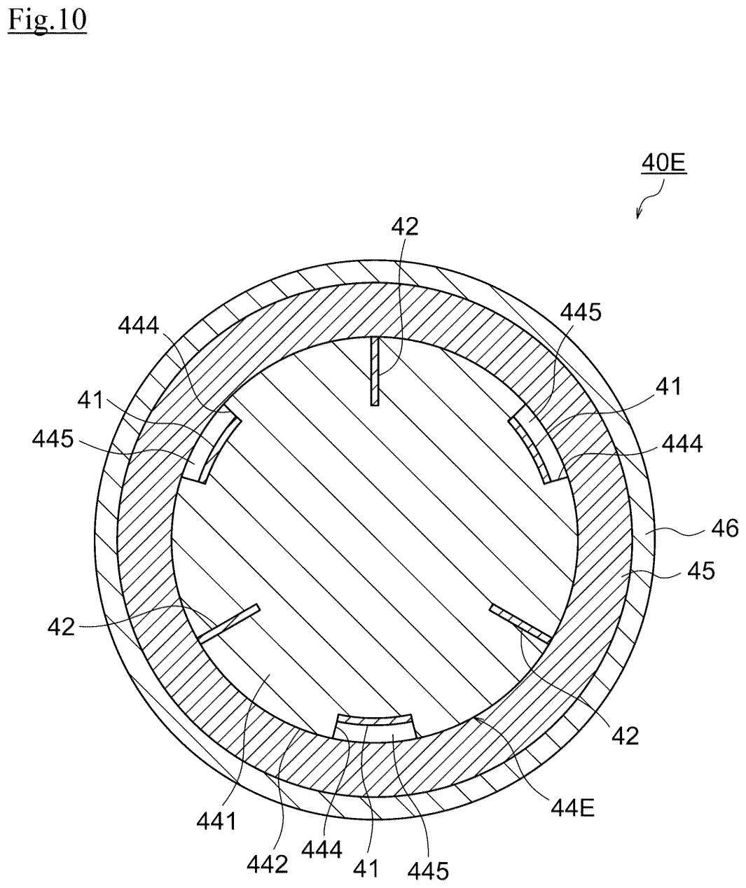

FIG. 10 is a sectional view showing the coaxial cable 40E in a fifth example of one or more embodiments. The present example is different from the third example in that the insulator 44E includes the air layer 445, but other configurations are the same as those of the third example. Hereinafter, the coaxial cable 40E in the fifth example will be described only with respect to differences from the third example, parts having the same configuration as those in the third example are denoted by the same reference numerals, and description thereof will be omitted.

As shown in FIG. 10, the insulator 44E in the present example includes the resin body 441 and the air layers 445. The resin body 441 of the present example has a columnar shape, and the resin body 441 has a plurality of grooves 444 (three in the present example) on its outer peripheral surface 442. Each of the grooves 444 is recessed toward the radial inside of the coaxial cable 40E and extends over the entire axial area of the coaxial cable 40E. The plurality of grooves 444 are arranged at substantially equal intervals in the circumferential direction of the coaxial cable 40E and are arranged concentrically with the outer conductor 45. The inner conductors 41 are respectively disposed at the bottoms of the grooves 444. The outer conductor 45 covers the outer peripheral surface 442 of the resin body 441, and the air that is present in each groove 444 forms the air layer 445. Therefore, each of the air layers 445 is interposed between the inner conductor 41 and the outer conductor 45.

Instead of the air layer 445, a gas other than air may be present in the groove 445, or the inside of the groove 445 may be a vacuum. Although the inner conductor 41 is exposed to the air layer 445 from the resin body 441 in FIG. 10, the inner conductor 41 may be completely embedded inside the resin body 441.

In the present example, similarly to the third example described above, because the coaxial cable 40E includes the plurality of inner conductors 41, it is possible to arrange the coaxial cables 40E in the motherboard 30 at high density.

Further, in the present example, similarly to the third example described above, because each of the plurality of inner conductors 41 has a thin cross-sectional shape extending in an arc shape, it is possible to reduce the reaction force of the coaxial cable 40E, to reduce the weight of the coaxial cables 40E, and to suppress formation of dew condensation inside the motherboard 30.

Further, in the present example, similarly to the third example described above, because each of the inner conductors 41 has a cross-sectional shape extending substantially parallel to the inner peripheral surface 451 of the outer conductor 45, a microstrip line structure is formed between the inner conductor 41 and the outer conductor 45.

Further, in the present example, similarly to the third example described above, because the wall-shaped conductor 42 is interposed between the inner conductors 41 adjacent to each other in the circumferential direction of the coaxial cable 40E, it is possible to suppress crosstalk between the plurality of inner conductors 41.

Furthermore, in the present example, the air layer 445 is interposed between the inner conductor 41 and the outer conductor 45, and the dielectric constant of the portion of the insulator 44E between the inner conductor 41 and the outer conductor 45 is reduced. Therefore, it is possible to increase the physical distance between the inner conductors 41 while maintaining the electrical distance between the inner conductor 41 and the outer conductor 45, and it is possible to suppress crosstalk between the plurality of inner conductors 41.

In the present example, the holes 443 described in the fourth example may be formed in the resin body 441 in addition to the grooves 444. It is possible to increase the electrical distance between the inner conductors 41 and to adjust the electrical distance between the inner conductors 41 by the hole 443.

Although the disclosure has been described with respect to only a limited number of embodiments, those skilled in the art, having benefit of this disclosure, will appreciate that various other embodiments may be devised without departing from the scope of the present disclosure. Accordingly, the scope of the disclosure should be limited only by the attached claims.

For example, in the third to fifth examples, the conductors 41 to 43 and the insulator 44 (44D and 44E) may be formed by twisting together a plurality of wires as in the second example.

### EXPLANATIONS OF LETTERS OR NUMERALS

1 . . . Device testing apparatus
10 . . . Tester
20 . . . DSA
21 . . . Socket
22 . . . Contactor
23 . . . Socket board
24 . . . Coaxial connector
30 . . . Mother board
31 . . . Housing
32 . . . Coaxial connector
40, 40B to 40E . . . Coaxial cable
41, 41B . . . Inner conductor
411 . . . Metal wire
42, 42B . . . Wall-shaped conductor
421 . . . One end
422 . . . Other end
423, 423a, 423b . . . Metal wire
43, 43B . . . Center conductor
431 . . . Metal wire
44, 44C to 44E . . . Insulator
441 . . . Resin body
442 . . . Outer peripheral surface
443 . . . Holl
444 . . . Groove
445 . . . Air layer
446 . . . Wire assembly
447 . . . Resin wire
45 . . . Outer conductor
451 . . . Inner peripheral surface
452 . . . Outer peripheral surface
453 . . . Room
46 . . . Jacket
70 . . . Test head
71 . . . Test module
72 . . . Cable
80 . . . Main frame
90 . . . Handler
91 . . . Chamber
92 . . . Opening
100 . . . DUT
110 . . . Terminal

What is claimed is:

1. A coaxial cable comprising:
a tubular outer conductor;
an insulator covered with the tubular outer conductor; and
inner conductors disposed in the insulator.

2. The coaxial cable according to claim 1, wherein the inner conductors in the insulator are spaced apart from each other.

3. The coaxial cable according to claim 1, wherein a cross section of each of the inner conductors has an arc shape.

4. The coaxial cable according to claim 1, wherein a cross section of each of the inner conductors is substantially parallel to an inner peripheral surface of the tubular outer conductor.

5. The coaxial cable according to claim 1, wherein in each of the inner conductors, a thickness in a radial direction of the coaxial cable is smaller than a width in a circumferential direction of the coaxial cable.

6. The coaxial cable according to claim 1, wherein the inner conductors are disposed at intervals in a circumferential direction of the coaxial cable and concentrically with the tubular outer conductor.

7. The coaxial cable according to claim 1, wherein each of the inner conductor comprises a metal layer having an arc-shaped cross-section.

8. The coaxial cable according to claim 1, wherein each of the inner conductors comprises metal wires arranged in an arc shape.

9. The coaxial cable according to claim 1, wherein the insulator is composed of a resin material.

10. The coaxial cable according to claim 9, wherein the insulator is a columnar or tubular resin body holding the inner conductors.

11. The coaxial cable according to claim 9, wherein the insulator comprises resin wires assembled together and holding the inner conductors.

12. The coaxial cable according to claim 9, wherein the insulator comprises a gas or a vacuum.

13. The coaxial cable according to claim 12, wherein the gas or the vacuum is interposed between the inner conductors.

14. The coaxial cable according to claim 12, wherein the gas or the vacuum is interposed between one of the inner conductors and the tubular outer conductor.

15. The coaxial cable according to claim 1, further comprising:
wall-shaped conductors interposed between the inner conductors in a circumferential direction of the coaxial cable, wherein
each of the wall-shaped conductors is electrically connected to the tubular outer conductor.

16. The coaxial cable according to claim 15, wherein the wall-shaped conductors are connected to each other at a center of the coaxial cable.

17. The coaxial cable according to claim 15, wherein each of the wall-shaped conductors comprises a metal layer having a cross section extending in a radial direction of the coaxial cable.

18. The coaxial cable according to claim 15, wherein each of the wall-shaped conductors comprises metal wires disposed in a radial direction of the coaxial cable.

19. A device testing apparatus that tests a device under test (DUT), comprising:
the coaxial cable according to claim 1.
